(19) United States
(12) Patent Application Publication
(10) Pub. No.: US 2017/0054100 A1
(43) Pub. Date: Feb. 23, 2017

(54) METHOD OF PREPARING A HOLE TRANSPORT LAYER HAVING IMPROVED HOLE MOBILITY

(71) Applicants: Rohm and Haas Electronic Materials LLC, Marlborough, MA (US); Dow Global Technologies LLC, Midland, MI (US)

(72) Inventors: Timothy S. De Vries, Midland, MI (US); Ashley S. Inman, Midland, MI (US); Kenneth L. Kearns, JR., Midland, MI (US); Chun Liu, Midland, MI (US); Travis E. McIntire, Midland, MI (US); Peter Trefonas, III, Medway, MA (US); William H. H. Woodward, Harbor Beach, MI (US)

(21) Appl. No.: 15/083,344

(22) Filed: Mar. 29, 2016

Related U.S. Application Data
(60) Provisional application No. 62/207,116, filed on Aug. 19, 2015.

(51) Int. Cl. H01L 51/50; H01L 51/56; H01L 51/00

(52) U.S. Cl. CPC H01L 51/5056; H01L 51/0003; H01L 51/0026; H01L 51/5072; H01L 51/56; H01L 2251/303; H01L 2251/301; H01L 2251/5369

(57) ABSTRACT

The present invention is directed to a process for preparing a hole transport layer in which a hole transport composition comprising a blend of a hole transport material and transition metal oxide or metal sulfide nanoparticles is deposited as a solution onto a substrate, such as an anode, and then is annealed in a subsequent step. It has been discovered that annealing the hole transport layer comprising the blend of an hole transport material and transition metal nanoparticles improves hole mobility of the hole transport layer in comparison to an identical hole transport layer that has not been subjected to an annealing step.

### RELATED APPLICATIONS

This application claims the benefit of priority under 35 U.S.C. §119(e) to U.S. Provisional Application No. 62/207,116, filed Aug. 19, 2015, which is incorporated herein by reference in its entirety.

### FIELD

The present invention relates generally to electronic devices incorporating organic light emitting diodes (OLEDs), and in particular, to compositions and processes for use in a hole transport layer of an OLED.

### BACKGROUND

Organic light emitting devices, such as an organic light emitting diode (OLED), are devices that are composed of films containing organic compounds as an electroluminescent layer. In a more sophisticated but common form, such devices may include anode and cathode layers between which are disposed one or more hole transport layers, one or more electron transport layers, and one or more emissive layers that are disposed between the hole transport and electron transport layers.

Generally, the application of a current to the device causes the anode to inject holes into the hole transport layer, and the cathode to inject electrons into the electron transport layer. The injected holes and electrons then each migrate toward the oppositely charged electrode. When an electron and a hole localize on the same molecule in the emissive layer, an “exciton,” which is a localized electron-hole pair having an excited energy state, is formed. Light is emitted when the exciton relaxes via a photoemissive mechanism.

In order to obtain high efficiency OLED devices it is important that the materials selected for the electron transport layer and the hole transport layer have efficient electron transport and hole transport, respectively. More particularly, to maximize OLED device efficiency it is important to achieve a balance of electron and hole transport into the one or more emissive layers of the device. Desirably, both the electron and hole transport layers comprise materials having high charge mobility (the rate at which the electron and hole moves through the material) so that both the electrons and holes are injected efficiently into the one or more emissive layers of the OLED device.

A wide variety of materials have been developed for use in a hole transport layer including both organic molecules and polymers. One example of an organic molecule for use as a hole transport material is N,N′-bis(naphthalene-1-yl)-N,N′-bis(phenyl)-benzidine (NPD).

Current methods of preparing OLED devices generally involve vapor deposition techniques which require a high vacuum, and typically result in waste of a large amount of materials in the process. Solution cast methods offer several advantages over vapor deposition techniques including lower costs. However, it is generally believed that solution cast materials have lower charge transport properties and lifetimes than devices prepared using vapor deposition.

Accordingly, there still exists a need for improved materials and processes for preparing a hole transport layer in an OLED device.

### SUMMARY

In a first aspect, the present invention is directed to a process for preparing a hole transport layer in which a hole transport composition comprising a blend of a hole transport material and transition metal oxide or metal sulfide nanoparticles is deposited as a solution onto a substrate, such as an anode, and then is annealed in a subsequent step.

It has been discovered that annealing the hole transport layer comprising the blend of an hole transport material and transition metal nanoparticles improves hole mobility of the hole transport layer in comparison to an identical hole transport layer that has not been subjected to an annealing step.

In one embodiment, the present invention comprises a process of preparing a hole transport layer comprising the steps of:

depositing a solution comprising a solvent and a blend of a hole transport layer material and transition metal nanoparticles overlying an anode;

drying the deposited solution to form a hole transport layer; and

annealing the hole transport layer.

In some embodiments, the process may also include one or more steps of depositing additional hole transport layers, one or more emissive layers overlying the hole transport layer; depositing a cathode layer; depositing one or more electron transport layers between the one or more emissive layers and the cathode; depositing one or more of an electron injection layer and a hole injection layer. In some embodiments, the invention may also include depositing one or more of a hole blocking layer and an electron blocking layer.

The hole transport layer comprises a blend of a hole transport material and nanoparticles comprised of a transition metal oxide nanoparticles. Transition metal nanoparticles that may be used in embodiments of the invention include Group V and VI transition metals. Preferably, the transition metal nanoparticles comprise oxides, selenides and sulfides of molybdenum, vanadium, and tungsten. In one embodiment, the transition nanoparticles comprise one or more of MoO₂, MoO₃, MoS₂, V₂O₅, VS₂, WO₂, WO₃, WS₂, MoSe₂, VSe₂, and WSe₂, and combinations thereof.

Embodiments of the invention are also directed to electronic devices incorporating a hole transport layer prepared in accordance with the present invention. In one embodiment, the present invention provides a film layer (e.g., a hole transport layer) comprising a blend of a hole transport material and transition metal nanoparticles in which the film layer has been subjected to an annealing step.

Embodiments of the invention provide films and devices that include a hole transport layer having improved hole mobility in comparison to an identical hole transport layer that has not been annealed. For example, when subjected to a step of annealing, a film comprising the hole transport layer exhibits an increase in mobility of at least two times, and in particular, at least ten times, and more particularly, at least one thousand times in comparison to an identical film that has not been subjected to an annealing step. In one embodiment, when subjected to an annealing step, a film formed from the hole transport layer exhibits an improvement in mobility that is between ten times and one hundred times when compared to an identical film that has not been subjected to an annealing step.

Aspects of the invention are also directed to films and articles comprising the hole transport layer. In one embodiment, the invention provides an electronic device comprising a pair of electrodes, and at least one hole transport layer comprising a blend of a hole transport material and transition metal nanoparticles sandwiched between the electrodes, and wherein the hole transport layer has been subjected to an annealing step.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is an example of an electronic device in accordance with embodiment of the invention;

FIG. 2 is a chart providing an example of raw data from a frequency-dependent impedance scan using complex admittance spectroscopy;

FIG. 3 is chart providing an example of a Poole-Frenkel mobility plot, having a positive linear slope;

FIG. 4 shows a complete experimental temperature profile for the annealing of the hole transport layer; and

FIG. 5 is a chart showing a complete annealing experiment of a single device.

### DETAILED DESCRIPTION OF THE INVENTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

As discussed previously, embodiments of the present invention provide a solution-based process of forming a hole transport layer in which a solution comprising a solvent, a hole transport material, and transition metal nanoparticles are solution deposited to form a hole transport layer that is then dried to form the hole transport layer. In a subsequent step, the hole transport layer is annealed to provide a hole transport layer having improved hole mobility in comparison to the same material that has not been annealed.

While not wishing to be bound by theory, it is believed annealing the hole transport layer results in diffusion of the transition metal within the layer such that the transition metal is more effectively distributed throughout the material. It is believed that the transition metal atoms act to help improve Poole-Frenkel mobility. Surprisingly, the inventors have discovered that when subjecting a hole transport layer in accordance with embodiments of the present invention, to a step of annealing, the hole transport layer exhibits an increase in mobility of at least two times, and in particular, at least ten times, and more particularly, at least one thousand times in comparison to an identical hole transport layer that has not been subjected to an annealing step. In one embodiment, when subjected to an annealing step, a film formed from the hole transport layer exhibits an improvement in mobility that is between ten times and one hundred times, when compared to an identical film that has not been subjected to an annealing step.

The solution comprising the solvent and the blend of a hole transport material and transition metal nanoparticles may be deposited using known solution process techniques including spin-coating, dip-coating, ink jet printing, and doctor blading. The use of solution based process techniques can be performed without using costly methods that require a vacuum, such as vapor deposition techniques.

In one embodiment, the present invention provides a process for preparing an OLED device that includes the steps of:

depositing a solution layer comprising a solvent, a hole transport material, and transition metal nanoparticles comprised of one or more of oxides and sulfides of a transition metal onto a substrate selected from an anode or a hole injection layer;

drying the solution layer to define a hole transport layer; and

annealing the hole transport layer, wherein the annealed hole transport layer exhibits an increase in hole mobility in comparison to an identical layer that has not been annealed.

Deposition of the layer, comprising the precursor of the hole transport layer, can be achieved by standard methods that are known to the skilled person and are described in the literature. Suitable and preferred deposition methods include liquid coating and printing techniques. Very preferred deposition methods include, without limitation, dip coating, spin coating, ink jet printing, nozzle printing, letter-press printing, screen printing, gravure printing, doctor blade coating, roller printing, reverse-roller printing, offset lithography printing, flexographic printing, web printing, spray coating, dip coating, curtain coating, brush coating, slot dye coating or pad printing.

Deposition of the solution layer comprising the hole transport material, transition metal nanoparticles, and solvent is typically performed at room temperature to 50 ° C. Removal of the solvent and any additional volatile additive(s) during the drying step may be achieved by evaporation, for example by exposing the deposited layer to high temperature and/or reduced pressure, preferably at 50 to 135° C.

After drying, the thickness of the hole transport layer may range from 1 to 500 nanometers (nm), more preferably from 2 to 150 nm, and even more preferably, from about 5 to 100 nm.

The annealing step can be performed immediately after deposition of the precursor for forming the hole transport layer, or at some later stage, such as following deposition of one or more deposition of one or more emissive layers, electron transport layers, and cathode. In one embodiment, the annealing step may be performed during a step of encapsulating the OLED device.

During the annealing step, the hole transport layer is heated to the annealing temperature of the hole transport material. In one embodiment, the hole transport layer is heated to or near the glass transition temperature of the hole transport material. For example, the hole transport material may be heated to a temperature that is within ±5° C. of the glass transition temperature of the hole transport material, and preferably within ±2° C. of the glass transition temperature of the hole transport material, and more preferably, within ±1° C. of the glass transition temperature of the hole transport material. Typical, annealing temperatures may range from 40 to100° C., and preferably, from about 60 to 100° C.

Following heating the hole transport material, the material may be slowly cooled at a predetermined rate until the temperature is desirably below the strain point of the material. For example, the hole transport material is cooled at a rate of l to 5° C./minute, and in particular, at a rate of 2 to 5° C./minute.

in further embodiments, the invention may also include the steps of:

i) forming a cathode overlying the hole transport layer;

ii) depositing one or more emissive layers that is disposed between the hole transport layer and the cathode; and

iii) depositing one or more electron transport layers disposed between the one or more emissive layers and the cathode

In addition to the above mentioned layers, the OLED device may include one or more of a substrate, a hole injection layer, a hole blocking layer, and an electron injection layer. Generally, the layers are deposited or formed in successive order, for example, the layers may be formed in the following order: 1) anode; 2) one or more hole injection layers; one or more hole transport layers; one or more emissive layers; one or more electron transport layers, and a cathode.

As discussed above, the hole transport layer is prepared from a solution comprising at least one of a solvent, hole transport material, and transition metal nanoparticles.

The transition metal nanoparticles comprise transition metal oxide or transition metal sulfide nanoparticles of Group V and VI transition metals (collectively referred to herein simply as transition metal nanoparticles). Preferably, the transition metal nanoparticles comprise oxides and sulfides of molybdenum, vanadium, and tungsten. In one embodiment, the transition nanoparticles comprise one or more of MoO₂, MoO₃, MoS₂, V₂O₅, VS₂, WO₂, WO₃, WS₂, MoSe₂, VSe₂, and WSe₂, and combinations thereof.

The transition metal nanoparticles have an average diameter ranging up to 100 nm, and preferably, from about 2 to 100 nm, and more preferably, from about 3 to 50 nm, and even more preferably, from about 10 to 20 nm.

The transition metal nanoparticles are generally present in a molar ratio of the transition metal nanoparticles to the hole transport material from 1:4 to 1:0.1, and in particular, from about 1:2.0 to 1:0.1, and more particularly, from about 1:1 to 1:0.1.

A wide variety of different hole transport materials may be used in embodiments of the present invention. More specifically, hole transport materials that may be used in the present invention include materials that can transport holes, are capable of being solvated and deposited on a substrate using solution based process techniques, such as those mentioned above. Hole transport materials may be intrinsic (undoped), or doped.

Suitable materials for the hole transport material may include small organic molecules, and polymers containing π-electron systems in the main chain or in pendant groups (e.g., π-conjugated polymers). For hole transport materials it may also be desirable that the material has a relatively low ionization energy ranging from about 4 to 7 eV, and in particular, from about 5 to 6 eV.

In one embodiment, the hole transport material may exhibit a triplet energy ranging from 1.5 to 3 eV, and preferably from 1.5 to 3 eV, and more preferably, from 2 to 3 eV.

In some embodiments, the hole transport material may have a HOMO (highest occupied molecular orbital) level ranging from about −4 to −7 eV, and in particular, from −5 to −7 eV, and more preferably, from −5 to −6 eV. The hole transport material may have a LUMO (lowest unoccupied molecular orbital) level from about −1 to −4 eV, and in particular, from −1 to −3 eV, and more preferably, from −2 to −3 eV. In one embodiment, the electron transport material has a triplet energy greater than −1 eV, and in particular, greater than −1.5 eV, and more particularly, greater than −2 eV.

In addition, hole transport materials for use in the present invention may also have relatively high glass transition temperatures. For example, the hole transport material may have a glass transition temperature ranging from 60 to 200° C., and typically, from 100 to 200° C., and more typically, from 80 to 160° C.

Generally, suitable small organic molecules include molecules having a plurality of aromatic ring systems, and that are capable of forming amorphous glass films. Typically, such molecules may have molecular weights ranging from 350 to 1,000 Daltons. Examples of suitable small organic molecules that may be used in embodiments of the present invention may include the following:

### N,N′-bis(3-methylphenyl)-N,N′-bis(phenyl)-benzidine (TPD)

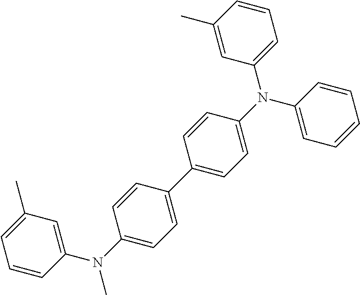 [SMILES: Cc1cccc(N(C)c2ccc(-c3ccc(N(c4ccccc4)c4cccc(C)c4)cc3)cc2)c1]

### N,N′-bis(naphthalene-1-yl)-N,N′-bis(phenyl)-benzidine (NPD)

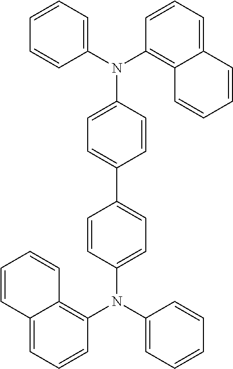 [SMILES: c1ccc(N(c2ccc(-c3ccc(N(c4ccccc4)c4cccc5ccccc45)cc3)cc2)c2cccc3ccccc23)cc1]

### Di-[4-(N,N-ditolyl-amino)-phenyl]cyclohexane (TAPC)

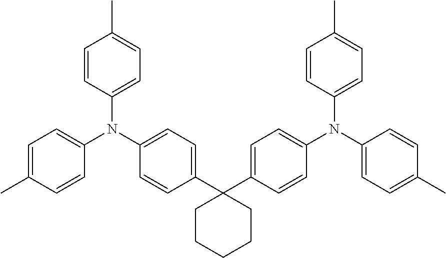

### Poly(3,4-ethylenedioxythiophene)-poly(styrenesulfonate) (PEDOT:PSS)

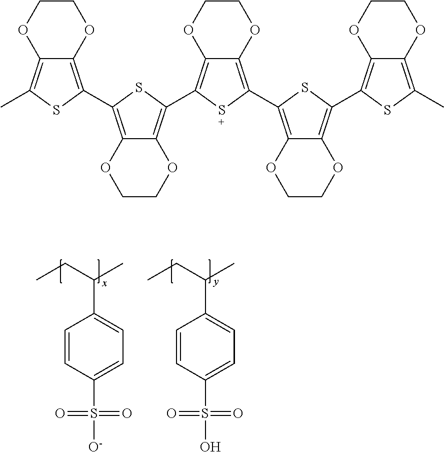

In addition to the molecules identified above, additional organic molecules that may be used in embodiments of the invention include tris[N-(1-naphthyl)-N-(phenylamino)]triphenylamine (1-NaphDATA), N,N′-bis(4-methylphenyl)-N,N′-bis(4-ethylphenyl)-[1,1′-(3,3′-dimethyl)biphenyl[-4,4′-diamine (ETPD)), tetrakis(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DUI), triphenylamine (TPA), bis[4-(N,N-diethylamino)-2-methylphenyl)(4-methylphenyl)methane (MPMP), 1-phenyl-3-[p-(diethylamino)styryl]-5-[p-(diethylamino)phenyl]pyrazoline (PPR or DEAS P), 1,2-trans-bis(9H-carbazol-9-yl)cyclobutane (DCZB), N,N,N′,N-tetrakis(4-methylphenyl)-(1,1′biphenyl)-4,4′-diamine (TTB), 4,4′,4″-tris(N,N-diphenylamino)triphenylamine (TDTA), 4,4′,4″-tris(N-carbazolyl)triphenylamine (TCTA), N,N′-bis(naphthalen-2-yl)-N,N′-bis(phenyl)benzidine (β-NPB), NN′-bis(3-methylphenyl)-N,N′-bis(phenyl)-9,9-spirobifluorene (Spiro-TPD), N,N′-bis(naphthalen-1-yl)-N,N′-bis(phenyl)-9,9-spirobifluorene (Spiro-NPB), N,N′-bis(3-methylphenyl)-N,N′-bis (phenyl)-9,9-dimethylfluorene (DMFL-TPD), di[4-(N,N-ditolylamino)phenyl]cyclohexane, bis(naphthalen-1-yl)-N,N′-bis(phenyl)-9,9-dimethylfluorene, N,N′-bis(naphthalen-1-yl)-N,N′-bis(phenyl)-2,2-dimethylbenzidine, N,N′-bis(naphthalen-1-yl)-N,N′-bis(phenyl)benzidine, N,N′-bis(3-methylphenyl)-N,N′-bis(phenyl)benzidine, 2,3,5,6-tetrafluoro-7,7,8,8-tetracyanoquinodimethane (F4-TCNQ), 4,4′,4″-tris(N-3-methylphenyl-N-phenylamino)triphenylamine, 4,4′,″-tris(N-(2-naphthyl)-N-phenyl-amino)triphenylamine, pyrazino[2,3-f][1,10]phenanthroline-2,3-dicarbonitrile (PPDN), methoxyphenyl)benzidine (MeO-TPD), 2,7-bis[N,N-bis(4-methoxyphenyl)amino]-9,9-spirobifluorene (MeO-Spiro-TPD), 2,2-bis[N,N-bis(4-methoxyphenyl)amino]-9,9-spirobifluorene (2,2′-MeO-Spiro-TPD), ditolylamino)phenyl]benzidine (NTNPB), N,N′-diphenyl-N,N′-di]4-(N,N-diphenylamino)phenyl]benzidine (NPNPB), N,N′-di(naphthalen-2-yl)-N,N′-diphenylbenzene-1,4-diamine (β-N,N′-bis(3-methylphenyl)-N,N′-bis(phenyl)-9,9-diphenylfluorene (DPFL-TPD), N,N′-bis(naphthalen-1-yl)-N,N′-bis(phenyl)-9,9-diphenylfluorene (DPFL-NPB), 2,2′,7,7′-tetrakis(N,N-diphenylamino)-9,9′-spirobifluorene (Spiro-TAD), 9,9-bis[4-(N,N-bis(biphenyl-4-yl)amino)phenyl]-9H-fluorene (BPA F), 9,9-bis[4-(N,N-bis(naphthalen-2-yl)amino)phenyl]-9H-fluorene (NPAPF), 9,9-bis[4-(N,N-bis(naphthalen-2-yl)-N,N′-bisphenylamino)phenyl]-9H-fluorene (NPBAPF), 2,2′,7,7′-tetrakis[N-naphthalenyl(phenyl)amino]-9,9′-spirobifluorene (Spiro-2NPB), N,N′-bis(phenanthren-9-yl)-N,N′-bis(phenyl)benzidine (PAPB) , 2,7-bis[N,N-bis(9,9-spirobifluoren-2-yl)amino]-9,9-spirobifluorene (Spiro-5), 2,2′-bis[N,N-bis(biphenyl-4-yl)amino]-9,9-spirobifluorene (2,2-Spiro-DBP), 2,2′-bis(N,N-diphenylamino)-9.9-spirobifluorene (Spiro-BPA), 2,2′,7,7′-tetra(N,N-ditolyl)aminospirobifluorene (Spiro-ITB), N,N,N′,N′-tetranaphthalen-2-ylbenzidine (TNB), porphyrin compounds and phthalocyanines such as copper phthalocyanines and titanium oxide phthalocyanines.

Polymers that may be used as the hole transport material may have a number average molecular mass (Mn) ranging from 2 to 100 kDa, and in particular, from 2 to 75 kDa and more particularly, from 3 kDa to 50 kDa. It should be recognized by one of ordinary skill in the art that the above molecular mass ranges are generally provided for polymers that have not undergone further processing, such as crosslinking of the polymer.

Hole-transporting polymers may include polyvinylcarbazoles, (phenylmethyppolysilanes and polyanilines. It is likewise possible to obtain e-transporting polymers by doping hole-transporting molecules into polymers such as polystyrene and polycarbonate. Suitable hole-transporting molecules are the molecules already mentioned above. Examples of polymers that may be used in embodiments of the present invention include:

### Poly[3-(carbazol-9-yl-methyl)-3-methyloxetane](PCMO)

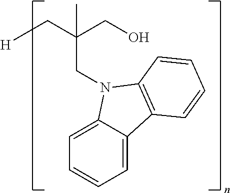

### Poly[3-(carbazol-9-yl)-9-(3-methyloxetan-3-ylmethyl)carbazole](PCOC)

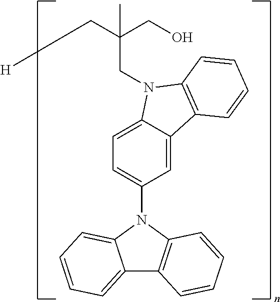

The solvent is generally selected based on its ability to dissolve the hole transport material, form a homogeneous solution with the transition metal nanoparticles, and be evaporated to form the hole transport layer.

Solvents that may be used in embodiments are selected from the group consisting of aromatic hydrocarbons, like toluene, o-, m-, or p-xylene, trimethyl benzenes (e.g., 1,2,3-, 1,2,4- and 1,3,5-trimethyl benzenes), tetralin, other mono-, di-, tri-, and tetraalkylbenzenes (e.g., diethylbenzenes, methylcumene, tetramethylbenzenes etc), anisole, alkyl anisoles (e.g., 2, 3 and 4 isomers of methylanisole, 2,3-, 2,4-, 2,5-, 2,6-, 3,4- and 3,5-isomers of dimethylanisole), naphthalene derivatives, alkyl naphthalene derivatives (e.g., 1- and 2-methylnaphthalene), di- and tetrahydronaphthalene derivatives. Also preferred are aromatic esters (e.g., alkyl benzoates), aromatic ketones (e.g., acetophenone, propiophenone), alkyl ketones (e.g. cyclohexanone), heteroaromatic solvents (e.g., thiophene, mono-, di-, and trialkyl thiophenes, 2-alkylthiazoles, benzthiazoles etc, pyridines), halogenaryles and anilin derivatives.

Preferred solvent include 3-fluoro-trifluoromethylbenzene, trifluoromethylbenzene, dioxane, trifluoromethoxybenzene, 4-fluoro-benzenetrifluoride, 3-fluoropyridine, toluene, 2-fluorotoluene, 2-fluoro-benzenetrifluoride, 3-fluorotoluene, pyridine, 4-fluorotoluene, 2,5-difluorotoluene, 1-chloro-2,4-difluorobenzene, 2-fluoropyridine, 3-chlorofluorobenzene, 1-chloro-2,5-difluoro-benzene, 4-chlorofluorobenzene, chlorobenzene, 2-chlorofluorobenzene, p-xylene, m-xylene, o-xylene, 2,6-lutidine, 2-fluoro-m-xylene, 3-fluoro-o-xylene, 2-chlorobenzenetrifluoride, dimethylformamide, 2-chloro-6-fluorotoluene, 2-fluoroanisole, anisole, 2,3-dimethylpyrazine, bromobenzene, 4-fluoroanisole, 3-fluoroanisole, 3-trifluoromethylanisole, 2-methylanisole, phenetol, benzenedioxol, 4-methylanisole, 3-methylanisole, 4-fluoro-3-methylanisole, 1,2-dichlorobenzene, 2-fluorobenzenenitril, 4-fluoroveratrol, 2,6-dimethylanisole, aniline, 3-fluorobenzenenitril, 2,5-dimethylanisole, 3,4-dimethylanisole, 2,4-dimethylanisole, benzenenitril, 3,5-dimethylanisole, N,N-dimethylaniline, 1-fluoro-3,5-dimethoxybenzene, phenylacetate, N-methylaniline, methylbenzoate, N-methylpyrrolidone, morpholine, 1,2-dihydro-naphthalene, 1,2,3,4-tetrahydronaphthalene, 3,4-dimethylanisole, o-tolunitril, veratrol, ethylbenzoate, N,N-diethylaniline, propylbenzoate, 1-methylnaphthalene, butylbenzoate, 2-methylbiphenyl, 2-phenylpyridin or 2,2′-B itolyl.

Embodiments of the invention further relate to an OLED device prepared from a formulation and/or process described above. In particular, embodiments of the present invention may be used to prepare a variety of OLED devices and structures.

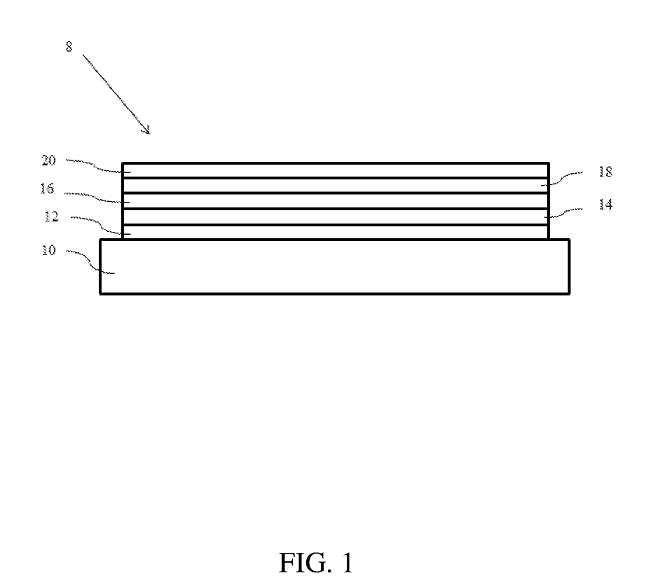

With reference to FIG. 1, an electronic device comprising an organic light emitting diode 8 is illustrated. The device 8 may include a substrate 10, an anode 12, a hole transport layer 14, an emissive layer 16, an electron transport layer 18, and a cathode 20. Device 8 may be fabricated by depositing the layers described, in order.

The hole transport layer 14 comprises a combination of a hole transport material and transition metal nanoparticles as described above.

Substrate 10 may be any suitable substrate that provides desired structural properties. Substrate 10 may be flexible or rigid. Substrate 10 may be transparent, translucent or opaque. Plastic and glass are examples of preferred rigid substrate materials. Plastic and metal foils are examples of preferred flexible substrate materials. Substrate 10 may be a semiconductor material in order to facilitate the fabrication of circuitry. For example, substrate 10 may be a silicon wafer upon which circuits are fabricated, capable of controlling OLEDs subsequently deposited on the substrate. Other substrates may be used. The material and thickness of substrate 10 may be chosen to obtain desired structural and optical properties.

Anode 12 may be any suitable anode that is sufficiently conductive to transport holes to the organic layers. Preferred anode materials include conductive metal oxides, such as indium tin oxide (ITO) and indium zinc oxide (IZO), aluminum zinc oxide (AlZnO), and metals. In some embodiments, anode 12 (and substrate 10) may be sufficiently transparent to create a bottom-emitting device. A preferred transparent substrate and anode combination is commercially available ITO (anode) deposited on glass or plastic (substrate).

Anode 12 may be opaque and/or reflective. A reflective anode 12 may be preferred for some top-emitting devices, to increase the amount of light emitted from the top of the device. The material and thickness of anode 12 may be chosen to obtain desired conductive and optical properties. Where anode 12 is transparent, there may be a range of thickness for a particular material that is thick enough to provide the desired conductivity, yet thin enough to provide the desired degree of transparency. Other anode materials and structures may be used.

In one embodiment, the material of anode 12 may have a work function higher than about 4 eV (a “high work function material”).

The one or more emissive layers 16 may include an organic material capable of emitting light when a current is passed between anode 12 and cathode 20. Preferably, emissive layer 16 contains a phosphorescent emissive material, although fluorescent emissive materials may also be used. Phosphorescent materials are preferred because of the higher luminescent efficiencies associated with such materials. Generally, the emissive layer 16 may comprise any phosphorescent compounds that are used in OLED devices.

Emissive layer 16 may also comprise a host material which may be capable of transporting electrons and/or holes, doped with an emissive material that may trap electrons, holes, and/or excitons, such that excitons relax from the emissive material via a photoemissive mechanism. Emissive layer 16 may comprise a single material that combines transport and emissive properties. Whether the emissive material is a dopant or a major constituent, emissive layer 16 may comprise other materials, such as dopants that tune the emission of the emissive material. Emissive layer 16 may include a plurality of emissive materials capable of, in combination, emitting a desired spectrum of light.

Emissive material may be included in emissive layer 16 in a number of ways. For example, an emissive small molecule may be incorporated into a polymer. This may be accomplished by several ways: by doping the small molecule into the polymer either as a separate and distinct molecular species; or by incorporating the small molecule into the backbone of the polymer, so as to form a co-polymer; or by bonding the small molecule as a pendant group on the polymer. Other emissive layer materials and structures may be used. For example, a small molecule emissive material may be present as the core of a dendrimer.

The electron transport layer 18 may include a material capable of transporting electrons. Electron transport layer may be intrinsic (undoped), or doped. A wide variety of electron transport materials may be used in embodiments of the present invention. For example, suitable materials for the electron transport material may include small organic molecules, and polymers containing π-electron systems in the main chain or in pendant groups (e.g., π-conjugated polymers). For electron transport materials it is also desirable that the material have a relatively shallow LUMO ranging from about −1.0 to −2.5 eV together with a deep HOMO ranging from −4.5 to −7.0 eV.

In one embodiment of the invention, electron transport materials may also be capable of being deposited via a solution based deposition process or a dry deposition process. Examples of solution based deposition are discussed previously, and may include spin coating, spray coating, slot-die printing, or ink-jet printing. Examples of a dry deposition process include physical vapor deposition, including evaporation and sublimation, chemical vapor deposition, organic molecular beam deposition, and molecular layer deposition. Dry deposition, in contrast to wet deposition methods, does not include solvation of the electron transport material in a solvent. Preferably, the electron transport material is deposited via a solution based deposition process.

In a solution deposition process, it may be desirable to select a solvent that will not adversely affect the previously deposited hole transition layer, such as solvating or partially solvating the hole transport material. In some embodiments, it may be desirable to first render the hole transport layer stable with respect to the deposition of the electron transport layer, such as through annealing, curing, or crosslinking of the hole transport layer.

A wide variety of materials may be used in preparing the cathode as in known in the art. Generally, the cathode may comprise any suitable material or combination of materials that are capable of conducting electrons and injecting them into the organic layers of the OLED device 8. The cathode 20 may be transparent, opaque, or reflective. In one embodiment, the cathode may comprise a single layer or may comprise multiple layers.

Generally, the cathode comprises a thin film of low work function metal or metallic alloy, such as below 4 eV. The low work function helps facilitate efficient electron injection into the LUMO of the electron transport layer or electron injection layer of the device. Examples of suitable materials for the cathode include Al, Ag, In, Mg, Ca, Li, Cs, and combinations thereof.

When present, the hole injection layer may comprise any material that is commonly used to form a hole injection layer. Examples of the material that can be used to form the hole injection layer include a phthalocyanine compound such as copperphthalocyanine, 4,4′,4″-tris(3-methylphenylphenylamino) triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS), but are not limited thereto.

Embodiments of the invention also provide a film formed from a composition comprising the blend of the hole transport material and the transition metal nanoparticles.

Embodiments of the invention also provide an article comprising at least one component formed from the hole transport layer composition. In a further embodiment, the article is an organic electroluminescent device.

Organic electroluminescent devices in accordance with embodiments of the invention may comprise a variety of different structures and configurations. For example, in one embodiment the device may comprise a pair of electrodes, and at least one hole transport layer sandwiched between the electrodes, and comprising a blend of a hole transport material and transition metal nanoparticles, wherein the hole transport layer has been subjected to an annealing step.

In one embodiment, the article may comprise a multi-layered structure having anode and cathode layers between which are disposed a hole transport layer, an electron transport layer in accordance with embodiments of the invention, and one or more emissive layers that are disposed between the hole transport and electron transport layers.

Other OLED devices that may be prepared in accordance with the present invention include, for example, devices having inverted structures, devices having one or more additional hole transport and electron transport layers in contact with the composition comprising the blend of the hole transport material and the transition metal nanoparticles, and devices comprising multiple electron transport and electron injection layers as well as one or more of hole transport and hole injection layers.

In one embodiment, after the device has been prepared, a film encapsulating layer is preferably deposited over the device. The thin film encapsulating layer encapsulates the layers of the device to provide protection from an external environment containing moisture and oxygen. The organic layer of the thin film encapsulating layer is formed of polymer, and may be a single layer or a stacked layer formed of any one of, for example, polyethyleneterephthalate, polyimide, polycarbonate, epoxy, polyethylene, and polyacrylate. In a preferred embodiment, the encapsulating layer comprises epoxy.

In addition to OLED devices, compositions of the present invention may be used in other electronic devices including, for example, organic photovoltaics, batteries, fuel cells, organic thin film transistors, organic supercapacitors, and the like.

### EXAMPLES

Tin-doped indium oxide (ITO) on glass with a sheet resistance less than 20 Ω/sq was purchased (Colorado Concept Coatings LLC, Loveland, Colo.). The thickness of the ITO was 150 nm, and the thickness of the glass was 2 mm.

Approximately 1 cm by 1 cm substrates were cut from the ITO and cleaned via the following procedure. First, substrates were boiled in acetone (HPLC grade, Fisher Scientific, Pittsburgh, Pa.). Then the substrates were sonicated for twenty minutes in fresh acetone. Then, the substrates were sonicated for twenty minutes in isopropanol (HPLC grade, Fisher Scientific, Pittsburgh, Pa.). Finally, the substrates were dried via a spin-coater at 2,000 rpm for 60 s (CB15 bowl and PWM32 controller, Headway Research, Inc., Garland, Tex.) and baked in a vacuum oven at 110° C. overnight (Model 19, Precision Scientific Co., Chennai, India).

Before coating, the substrates were treated in a UV-Ozone treater (PSD-UV, Novascan Technologies, Inc., Ames, Iowa) and cooled to −78.5° C. by placing them onto a bed of dry ice under aluminum foil. A blanket of carbon dioxide from the dry ice prevented condensation from occurring on or near the substrates.

The hole transport layer solutions, described below, were deposited onto the cold substrates via a pipette, and the entire setup was transferred into the antechamber of a nitrogen-purged glove box with an oxygen level less than 3 ppm (Nexus II, Vacuum Atmospheres Co., Topsfield, Mass.). The antechamber was evacuated and left under vacuum overnight so that the solvent of the hole transport layer solutions could evaporate, leaving a glassy layer behind.

The hole transport layer solutions were made in the glove box as follows. N,N′-Di(1-naphtyl)-N,N′-diphenyl-(1,1′-biphenyl)-4,4′-diamine (NPD) available from Luminescence Technology Corp., Hsin-Chu, Taiwan, was used as the hole transport material. The NPD was then sublimed and the purity was confirmed to be greater than 99.5% via liquid chromatography. The NPD was then added to two clean glass scintillation vials and weighed. Then, enough solvent (toluene or dichloromethane, Fisher Scientific, Pittsburgh, Pa.) was added to reach the desired concentration. Molybdenum trioxide nanoparticles (99.94% pure, 13-90 nm, orthorhombic crystal, US Research Nanomaterials, Inc., Houston, Tex.) were added to new, clean vials, which were subsequently weighed. Finally, an amount of the NPD solutions was added to each vial to reach the desired MoO₃:NPD molar ratio. The weighed amounts and final concentrations of the methylene chloride solutions are shown in Table 1. Only one solution of toluene was made, with a molar ratio of 4 mol NPD to 1 mol MoO₃.

TABLE 1
Desired and final concentrations of MoO₃ in NPD.

| | | | | Actual Molar |
|---|---|---|---|---|
| | Target | | 0.347 wt % NPD | Ratio (mol |
| SAMPLE | MoO₃:NPD | MoO₃ | in MeCl | NPD:1.0 mol |
| No. | Molar Ratio | Added (g) | Solution Added (g) | MoO₃) |
| 5 | 1.0:10.0 | 0.0034 | 38.0386 | 9.484671094 |
| 4 | 1.0:4.0 | 0.002 | 9.3588 | 3.967042365 |
| 3 | 1.0:2.0 | 0.0028 | 6.5928 | 1.996128694 |
| 2 | 1.0:1.0 | 0.0034 | 4.11 | 1.024801076 |
| 1 | 1.0:0.1 | 0.012 | 1.3858 | 0.097902995 |
| 6 | No MoO₃ | — | — | — |
| | Added | | | |

The hole transport materials of Table 1, were then cast onto the substrates drop-wise with a glass pipette. The solution layer that then dried via a vacuum to remove the solvent.

After the hole transport layers were deposited onto the ITO substrates, aluminum cathodes were deposited via atomic layer deposition (Amod Evaporator, Angstrom Engineering, Kitchener, Ontario, Canada). The aluminum (99.99%, Angstrom Engineering, Kitchener, Ontario, Canada) was evaporated to 50 nm at 2 Å/s and masked such that each substrate/device received a single circular electrode with a diameter of 3 mm.

The completed, working devices were then removed from the vacuum chamber and stored under dry nitrogen until measured for mobility. NPD was chosen as a hole transport layer in this study since it is a very common molecule in OLED literature. However, it tends to crystallize when cast from solution. Casting at dry ice temperatures under vacuum helps reduce the amount of crystallization, but it does not eliminate it entirely. Small crystallites can be seen with the naked eye, and it is difficult to elucidate the percent area of crystallization under the deposited aluminum cathode. As crystalline NPD does not conduct electricity, it is impossible to know the exact area of conductivity. A traditional method of measuring mobility utilizes current/voltage measurements via the Mott-Gurney equation:

$$μ = \frac{8}{9} \frac{{Id}^{3}}{{A V}^{2} {ɛɛ}_{0}} \qquad ( 1 )$$

where μ is the mobility, I is the current, d is the thickness, A is the area, V is the voltage, ε is the dielectric constant, and ε₀ is the permittivity of vacuum. However, the area of the device must be known. The Mott-Gurney equation can be manipulated such that mobility is determined via transport time and not current:

$$μ = η \frac{{d}^{2}}{τ V} \qquad ( 2 )$$

where η is a constant to calibrate for stray fields and an AC signal (empirically determined in the art to be 1.0) and τ is the transit time. The use of this equation to determine mobility is known as complex admittance spectroscopy and is becoming very common in the optoelectronic device field. Although the area of the device is not required to determine mobility using Equation 2, the device thickness is required. However, the assumption here is that the area of the individual devices is not consistent as crystallization is difficult to control, but the device thickness is relatively consistent as the same amount of NPD was cast onto each substrate via a glass pipette. Therefore, Equation 2 can be simplified as the proportionality fₘₐₓ/V ∝ μ. That is to say, the frequency at which complex admittance spectroscopy identifies as the transit time (fₘₐₓ=1/τ) divided by the voltage is proportional to the mobility, and given a constant thickness devices should be comparable to each other in this regard.

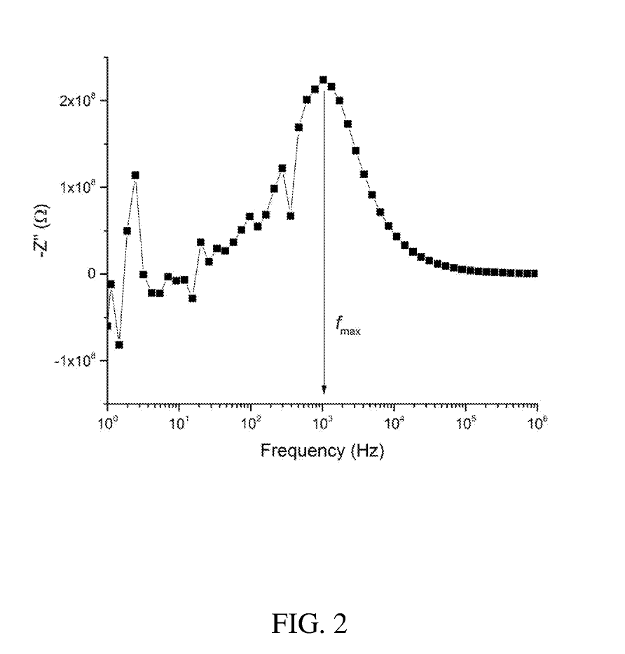

The devices were measured using a Novocontrol Alpha-A Dielectric Spectrometer and temperature was controlled using an integrated liquid nitrogen cryostat (NOVOCONTROL Technologies GmbH & Co. KG, Montabaur, Germany). Devices were measured from 10⁰ Hz to 10⁶ Hz at 0.1 V AC with an offset DC bias from 0 to 15 V. Contact was made to the ITO anode and the aluminum cathode via thin gold wires. An example of a measurement at a single voltage is shown in FIG. 2.

It is important to consider the voltage-dependence of the mobility, as device conductivity can be due to several different mechanisms. Virtually any material will conduct some electricity, but most materials will follow Kirchhoff's Laws and exhibit a linear relationship between current and voltage (i.e. Ohm's Law). When such data is inserted into Equation 1, a negative relationship is found between mobility and voltage. However, organic semiconductors are known to exhibit a positive correlation between mobility and voltage. Specifically, they follow the Poole-Frenkel effect:

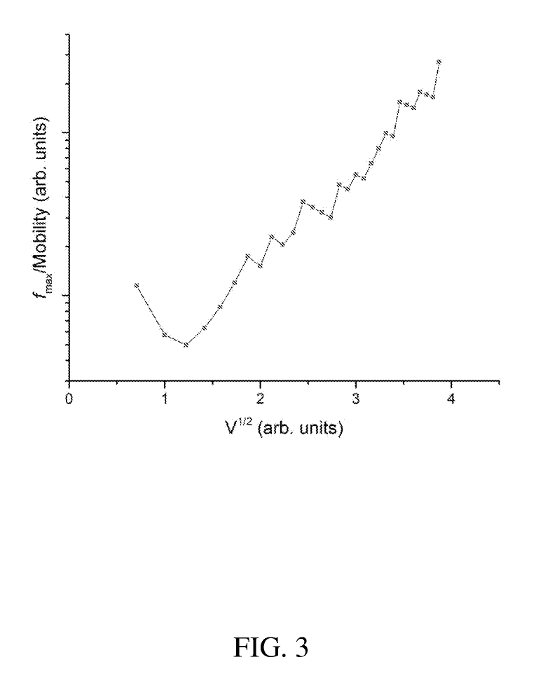

μ=μ₀e^{β\sqrt{V/d}} (3)

where μ₀ is the zero field mobility and β is the Poole-Frenkel constant. The Poole-Frenkel effect in organic semiconductors is associated with electron hopping between molecular orbitals. It is clear, when examining this equation, that a plot of log μ versus V^{1/2} should yield a positive linear slope; anything else suggests non-Poole-Frenkel conductivity or poor hole injection. With reference to FIG. 3, an example of a device measured at different voltages is provided. One can see a linear slope. More particularly, FIG. 3 provides evidence Poole-Frenkel mobility in the examples discussed here. The deviation at low voltages was due to poor injection of holes into the device.

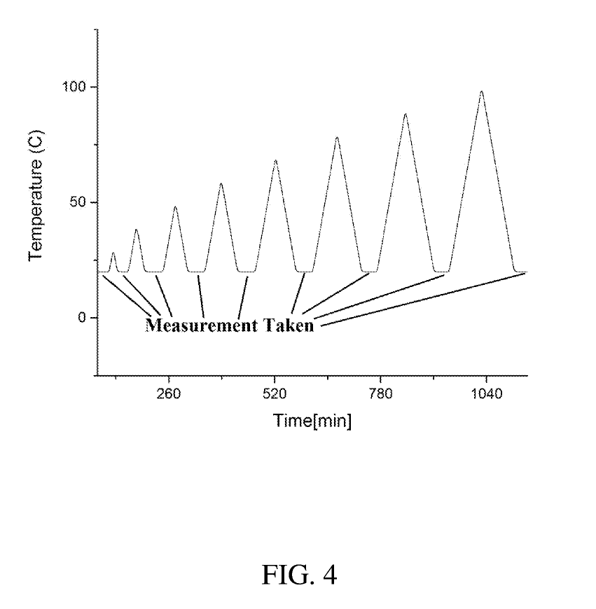

Each of the devices prepared from Samples 1-6, as described above, were measured at 20° C., heated to increasingly large temperatures at 1° C/min., and then cooled to 20° C. to be measured again. The slow temperature ramp rate was to reduce overshooting the desired temperature. The annealing temperatures were in 10° C. increments, up to 100° C. A complete experimental temperature profile is shown in FIG. 4.

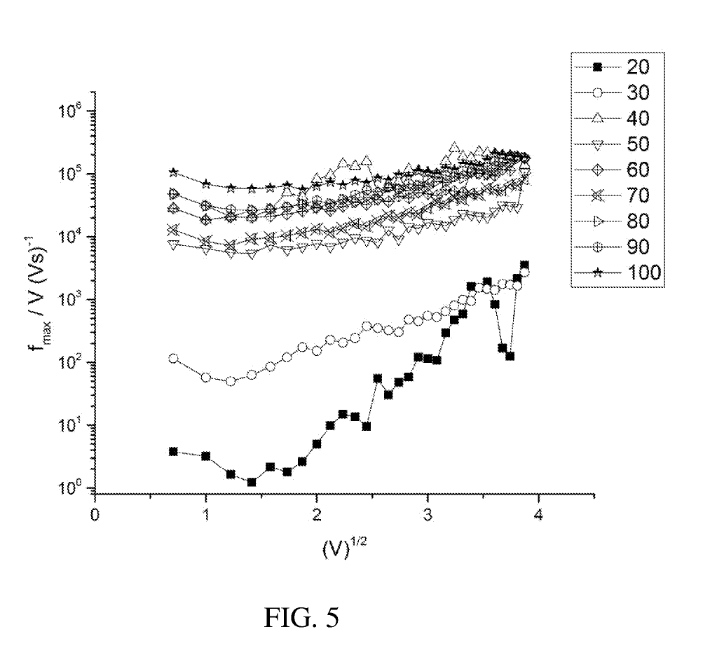

FIG. 5 provides an example of a complete annealing experiment of a single device. It can be seen that the positive correlation between the maximum frequency and the voltage is maintained, suggesting no irreparable damage or otherwise change in the mobility mechanism (i.e., Poole-Frenkel) of the device throughout the experiment. This result is very important, as it properly highlights the improvements in hole mobility while maintaining the usefulness of the material as a hole transport layer. It is possible to dope a transport layer with a metal or other conductive material to such high concentrations as to make a completely conductive layer. This is commonly performed in polymers by adding silver or carbon black. However, in the inventive hole transport material, the demonstration of Poole-Frenkel mobility as evidenced by the positive linear slopes in FIG. 5 supports the proposition that the basic transport mechanism of the layer has not been altered, and the layer can still perform its function in an optoelectronic device.

The hole mobility results for Samples 1-6 are provided in Tables 2A and 2B below.

TABLE 2A
EVALUATION OF ANNEALING TEMPERATURE ON HOLE MOBILITY

| | Sample 1 | | | | | Sample 3 |
|---|---|---|---|---|---|---|
| | relative | Sample 1 | Sample 2 | Sample 2 | Sample 3 | Normalized |
| | hole | Normalized | relative hole | Normalized | relative hole | to |
| Temperature | mobility | to minimum | mobility | to minimum | mobility | minimum |
| (° C.) | (fₘₐₓ) | mobility | (fₘₐₓ) | mobility | (fₘₐₓ) | mobility |
| 20 | * | n/a | 1436919 | 1.36 | 9.14 | 1 |
| 30 | n/a | n/a | 136989.4 | 1.13 | 570631.5 | 5.99 |
| 40 | n/a | n/a | 417809.1 | 1.24 | 1388400 | 6.39 |
| 50 | n/a | n/a | 33693.73 | 1 | 2800027 | 6.71 |
| 60 | n/a | n/a | 67570.44 | 1.07 | 1310815 | 6.37 |
| 70 | n/a | n/a | 382730.1 | 1.23 | 2591557 | 6.67 |
| 80 | n/a | n/a | 200107.2 | 1.17 | 560821.1 | 5.98 |
| 90 | n/a | n/a | 351328.8 | 1.225 | 468989 | 5.90 |
| 100 | n/a | n/a | 458686.9 | 1.25 | 622447.6 | 6.03 |

* Device short (conductivity above measurement range).

TABLE 2B
CONTINUED

| | Sample 4 | | Sample 5 | | | Sample 6 |
|---|---|---|---|---|---|---|
| | relative | Sample 4 | relative | Sample 5 | Sample 6 | Normalized |
| | hole | Normalized | hole | Normalized | relative hole | to |
| Temperature | mobility | to minimum | mobility | to minimum | mobility | minimum |
| (° C.) | (fₘₐₓ) | mobility | (fₘₐₓ) | mobility | (fₘₐₓ) | mobility |
| 20 | 7.46E+01 | 1 | 5.74E+01 | 1 | 277 | 1.05 |
| 30 | 1135.705 | 1.63 | 7.46E+01 | 1.06 | 360 | 1.1 |
| 40 | 689067.4 | 3.12 | 12065.38 | 2.32 | 213 | 1 |
| 50 | 41591.13 | 2.47 | 4611142 | 3.79 | 360 | 1.1 |
| 60 | 152082.3 | 2.77 | 169375.4 | 2.97 | 468 | 1.15 |
| 70 | 71948.54 | 2.597 | 100644.8 | 2.85 | 277 | 1.05 |
| 80 | 177418.1 | 2.807 | 208307.5 | 3.02 | 277 | 1.05 |
| 90 | 206076.9 | 2.84 | 287875.2 | 3.10 | 277 | 1.05 |
| 100 | 354493.3 | 2.96 | 127638.5 | 2.90 | 608 | 1.20 |

From Tables 2A and 2B, it can be seen that for Samples 2-5 annealing the hole transport layer generally resulted in an increase in the maximum frequency (“Hole mobility” columns), which is indicative of an increase in hole mobility in comparison to the same samples evaluated initially, before annealing, at 20° C. Sample 6, which did not include any of the transition metal nanoparticles, did not appear to show any improvement in hole mobility. In general, annealing of the samples resulted in significant improvements in hole mobility. Additionally, each of these samples displayed a mobility plot indicative of Poole-Frenkel mobility throughout the lifetime of the test, suggesting that annealing these samples even above the glass transition temperature of the material did not destroy the desirable hole transport behavior of the device. This supports the hypothesis that the metal atoms improve π-orbital overlap or connect non-overlapping π-orbitals by forming extended η-complexes.

Sample 1, with highest doping of molybdenum showed a negative slope, which indicated a device short. Therefore it was not tested fully, as such a material would not be effective as a hole transport layer and was therefore out of the scope of this example. Sample 2 was measured incorrectly initially, as the proportional-integral-derivative temperature controller malfunctioned and increased the temperature an unknown amount before settling to 20° C., effectively annealing the sample. Therefore, although it had less of a normalized mobility increase, its mobility measurements were still in the range of the other annealed samples, suggesting that it also benefited from an improved mobility.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of forming an electronic device comprising the steps of:
depositing a solution layer comprising a solvent, a hole transport material, and transition metal nanoparticles comprised of one or more of oxides, sulfides or selenides of a transition metal onto a substrate selected from an anode or a hole injection layer;
drying the solution layer to define a hole transport layer; and
annealing the hole transport layer, wherein the annealed hole transport layer exhibits an increase in hole mobility in comparison to an identical layer that has not been annealed.

2. The method of claim 1, further comprising the step of depositing a cathode layer above the hole transport layer.

3. The method of claim 1, further comprising the step of depositing one or more emissive layers overlying the hole transport layer.

4. The method of claim 1, further comprising the step of depositing an electron transport layer overlying the hole transport layer.

5. The method of claim 1, wherein the transition metal nanoparticles are selected from the group consisting of MoO₂, MoO₃, MoS₂, V₂O₅, VS₂, WO₂, WO₃, WS₂, MoSe₂, VSe₂, and WSe₂, and combinations thereof.

6. The method of claim 1, wherein the transition metal nanoparticles have an average diameter ranging up to 100 nanometers.

7. The method of claim 1, wherein the transition metal nanoparticles are present in a molar ratio of the transition metal to the hole transport material from 1:4 to 1:0.1.

8. The method of claim 1, wherein the annealed hole transport layer exhibits an increase in hole mobility of at least two times in comparison to an identical layer that has not been subjected to an annealing step.

9. The method of claim 1, wherein the annealed hole transport layer exhibits an increase in hole mobility of at least ten times in comparison to an identical layer that has not been subjected to an annealing step.

10. A solution deposited hole transport layer comprising a blend of a hole transport material and transition metal nanoparticles comprising one or more of oxides, sulfides and selenides of a transition metal, wherein the hole transport layer has been deposited as a solution onto a substrate, and then subjected to annealing, and wherein the hole transport layer exhibits an increase in hole mobility in comparison to an identical layer that has not been annealed.

11. The hole transport layer of claim 10, wherein the transition metal nanoparticles are selected from the group consisting of MoO₂, MoO₃, MoS₂, V₂O₅, VS₂, WO₂, WO₃, WS₂, MoSe₂, VSe₂, and WSe₂, and combinations thereof.

12. The hole transport layer of claim 10, wherein the transition metal nanoparticles have an average diameter ranging up to 100 nanometers.

13. The hole transport layer of claim 10, wherein the transition metal nanoparticles are present in a molar ratio of the transition metal to the hole transport material from 1:4 to 1:0.1.

14. An article formed from the hole transport layer of claim 10.

15. An electronic device comprising a pair of electrodes and at least one hole transport layer disposed therebetween, the hole transport layer comprising a blend of a hole transport material and transition metal nanoparticles comprising one or more of oxides, selenides and sulfides of a transition metal, wherein the hole transport layer has been subjected to annealing and exhibits an increase in hole mobility in comparison to an identical layer that has not been annealed.

16. The device of claim 15, wherein the transition metal nanoparticles are selected from the group consisting of MoO₂, MoO₃, MoS₂, V₂O₅, VS₂, WO₂, WO₃, WS₂, MoSe₂, VSe₂, and WSe₂, and combinations thereof.

17. The device of claim 15, wherein the transition metal nanoparticles have an average diameter ranging from about 2 to 100 nanometers.

18. The device of claim 15, wherein the transition metal nanoparticles are present in a molar ratio of the transition metal to the hole transport material from 1:10 to 1:0.1.

19. The device of claim 15, further comprising one or more emissive layers overlying the hole transport layer, and an electron transport layer disposed between one of the electrodes and the one or more emissive layers.

20. The device of claim 15, wherein the annealed hole transport layer exhibits an increase in hole mobility of at least two times in comparison to an identical layer that has not been subjected to an annealing step.
